(19) United States
(12) Patent Application Publication
(10) Pub. No.: US 2021/0126247 A1
(43) Pub. Date: Apr. 29, 2021

(54) DIELECTRIC COATED LITHIUM METAL ANODE

(71) Applicant: Applied Materials, Inc., Santa Clara, CA (US)

(72) Inventors: Subramanya P. HERLE, Mountain View, CA (US); David Masayuki ISHIKAWA, Mountain View, CA (US)

(21) Appl. No.: 17/074,147

(22) Filed: Oct. 19, 2020

Related U.S. Application Data
(60) Provisional application No. 62/926,731, filed on Oct. 28, 2019.

(51) Int. Cl. H01M 4/1395; C23C 14/56; C23C 14/24; C23C 14/30; C23C 14/34; H01M 4/38; H01M 4/36; H01M 4/134; H01M 4/62; H01M 4/04; C23C 14/14

(52) U.S. Cl. CPC H01M 4/1395; C23C 14/568; C23C 14/24; C23C 14/30; C23C 14/34; H01M 4/382; H01M 2004/027; H01M 4/134; H01M 4/628; H01M 4/0404; H01M 4/0426; C23C 14/14; H01M 4/0423; H01M 4/366

(57) ABSTRACT

A method and apparatus for forming an anode electrode structure are provided. The deposition apparatus comprises a first spool chamber capable of housing a storage spool operable to provide the flexible substrate. The deposition apparatus further comprises a first deposition chamber arranged downstream from the first spool chamber. The first deposition chamber comprises a first coating drum capable of guiding the flexible substrate past a first plurality of deposition units capable of depositing lithium metal on the flexible substrate. The deposition apparatus further comprises a second deposition chamber arranged downstream from the first deposition chamber. The second deposition chamber comprises a second coating drum capable for guiding the flexible substrate past a second deposition unit comprising an evaporation crucible capable of depositing a ceramic protective film on the lithium metal film.

### CROSS-REFERENCE TO RELATED APPLICATIONS

This application claims benefit of U.S. provisional patent application Ser. No. 62/926,731, filed Oct. 28, 2019. The aforementioned related patent application is herein incorporated by reference in its entirety.

### BACKGROUND

### Field

Implementations described herein generally relate to metal electrodes, more specifically lithium-containing anodes, high performance electrochemical devices, such as primary and secondary electrochemical devices, including the aforementioned lithium-containing electrodes, and methods for fabricating the same.

### Description of the Related Art

Lithium (Li) ion batteries have played a vital role in the development of current generation mobile devices, microelectronics and electric vehicles. A typical Li-ion battery is made of a positive electrode (cathode), a negative electrode (anode), an electrolyte to conduct ions, a porous separator membrane (electrical insulator) between the two electrodes to keep them physically apart and the packaging. Current Li-ion batteries have energy densities ranging around 650 Wh/l. Theoretical specific capacity of the current anode (graphite) at 372 mAh/g limits enhancing the energy density of the batteries. In comparison, a lithium metal anode offers a theoretical specific capacity of 3860 mAh/g (˜10 times that of graphite) and a silicon anode offers 4200 mAh/g (˜12 times that of graphite). To achieve energy densities higher than 1000 VVh/l, high specific capacity electrodes such as lithium metal anodes or silicon-graphite anodes are needed.

A critical aspect of lithium metal anodes is the formation of dendrites during battery charging. Dendrites are basically whiskers of lithium that grow inside batteries, and can cause batteries to lose power more quickly, short out, or even in some instances to catch fire. Dendrites are typically blocked by the porous separator membrane, which is positioned in between the lithium metal anode and the cathode. However, some dendrites grow so fast and rigid that these dendrites actually pierce the porous membrane separator positioned between the electrodes, which in turn, short the lithium battery, and in some instances, lead to spontaneous combustion. The risks of short circuit by formation of dendrites is one reason why the development of Li-ion batteries has not been possible.

In either of the above cases, the formation of a stable (chemically and structurally) and conducting layer will greatly benefit the anodes. Approaches so far have focused on utilizing one of two options. In one approach, a rigid ceramic layer, which is ion conducting, is used to prevent the growth of dendrites. This approach has been attempted with various ceramic layers such as for example lithium phosphorous sulfides. In another approach, an electronic conducting layer is used to promote electronic conductivity. However, usage of a predominantly single conduction layer typically leads to an increase in overall cell resistance.

Therefore, there is a need for improved materials for protecting electrodes.

### SUMMARY

Implementations described herein generally relate to metal electrodes, more specifically lithium-containing anodes, high performance electrochemical devices, such as primary and secondary electrochemical devices, including the aforementioned lithium-containing electrodes, and methods for fabricating the same. In one aspect, a deposition apparatus operable to coat a flexible substrate is provided. The deposition apparatus comprises a first spool chamber capable of housing a storage spool operable to provide the flexible substrate. The deposition apparatus further comprises a first deposition chamber arranged downstream from the first spool chamber. The first deposition chamber comprises a first coating drum capable of guiding the flexible substrate past a first plurality of deposition units capable of depositing a lithium metal film on the flexible substrate. The deposition apparatus further comprises a second deposition chamber arranged downstream from the first deposition chamber. The second deposition chamber comprises a second coating drum capable for guiding the flexible substrate past a second deposition unit comprising an evaporation crucible capable of depositing a ceramic protective film on the lithium metal film. The deposition apparatus further comprises a second spool chamber arranged downstream from the second deposition chamber and capable of housing a wind-up spool operable to wind the flexible substrate thereon after deposition. The deposition apparatus further comprises a roller assembly capable of transporting the flexible substrate along a partially convex and partially concave substrate transportation path from the first spool chamber to the second spool chamber.

In another aspect, a method is provided. The method comprises transferring a flexible substrate from a storage spool in a first spool chamber to a first deposition chamber arranged downstream from the first spool chamber. The first deposition chamber comprises a first coating drum capable of guiding the flexible substrate past a first plurality of deposition units capable of depositing lithium metal on the flexible substrate. The method further comprises guiding the flexible substrate past the first plurality of deposition units while depositing a lithium metal film on the flexible substrate via the first plurality of deposition units. The method further comprises transferring the flexible substrate from the first deposition chamber to a second deposition chamber. The second deposition chamber comprises a second coating drum capable of guiding the flexible substrate past a second deposition unit. The second deposition unit comprises an evaporation crucible capable of depositing a ceramic protective film on the lithium metal film. The method further comprises guiding the flexible substrate past the evaporation crucible while depositing a ceramic protective film on the lithium metal film via the evaporation crucible.

In yet another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above-recited features of the present disclosure can be understood in detail, a more particular description of the implementations, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 illustrates a schematic cross-sectional view of one implementation of an energy storage device incorporating an electrode structure formed according to one or more implementations described herein;

FIG. 2 illustrates a cross-sectional view of one implementation of a dual-sided anode electrode structure formed according to one or more implementations described herein;

FIG. 3 illustrates a schematic side view of a deposition system according to one or more implementations described herein; and

FIG. 4A illustrates a schematic top view of an evaporation apparatus for forming a ceramic-coated electrode structure according to implementations described herein;

FIG. 4B illustrates a schematic front view of the evaporation apparatus shown in FIG. 4A; and

FIG. 4C illustrates a schematic top view of the evaporation apparatus shown in FIG. 4A; and

FIG. 5 illustrates a process flow chart summarizing one implementation of a method for forming an electrode structure according to implementations described herein.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

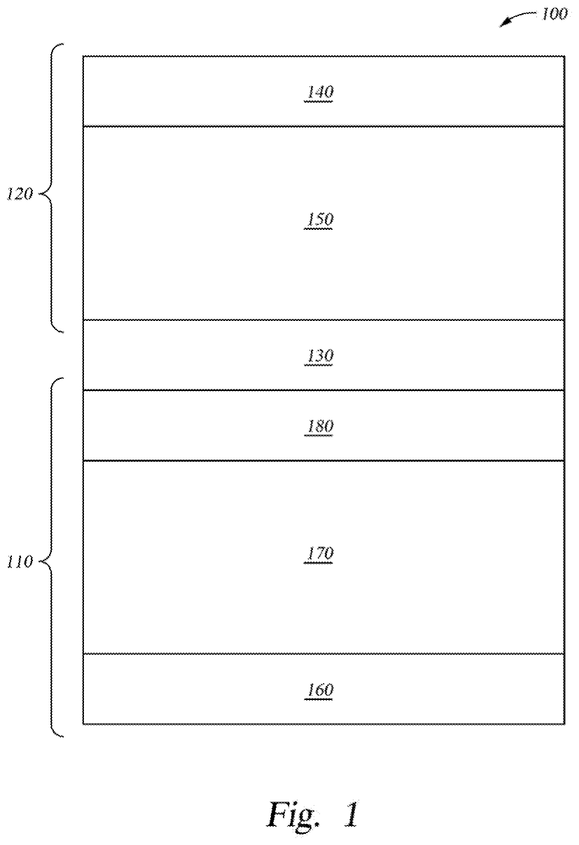

The following disclosure describes anode electrodes, high performance electrochemical cells and batteries including the aforementioned anode electrodes, and methods for fabricating the same. Certain details are set forth in the following description and in FIGS. 1-5 to provide a thorough understanding of various implementations of the disclosure. Other details describing well-known structures and systems often associated with electrochemical cells and batteries are not set forth in the following disclosure to avoid unnecessarily obscuring the description of the various implementations.

Many of the details, dimensions, angles and other features shown in the Figures are merely illustrative of particular implementations. Accordingly, other implementations can have other details, components, dimensions, angles and features without departing from the spirit or scope of the present disclosure. In addition, further implementations of the disclosure can be practiced without several of the details described below.

Implementations described herein will be described below in reference to a high rate evaporation process that can be carried out using a roll-to-roll coating system, such as TopMet™, SmartWeb™, and TopBeam™ all of which are available from Applied Materials, Inc. of Santa Clara, Calif. Other tools capable of performing vapor deposition processes (e.g., physical vapor deposition (PVD) processes, chemical vapor deposition (CVD) processes, atomic layer deposition (ALD) processes) may also be adapted to benefit from the implementations described herein. In addition, any system enabling the vapor deposition processes described herein can be used to advantage. The apparatus description described herein is illustrative and should not be construed or interpreted as limiting the scope of the implementations described herein. It should also be understood that although described as a roll-to-roll process, the implementations described herein may be performed on discrete polymer substrates.

As described herein, flexible substrates can be considered to include among other things, films, foils, webs, strips of plastic material, metal, paper, or other materials. Typically, the terms “web,” “foil,” “strip,” “substrate” and the like are used synonymously.

Energy storage devices, for example, Li-ion batteries, typically include a positive electrode (e.g., cathode), and a negative electrode separated by a polymer separator with a liquid electrolyte. Solid-state batteries also typically include a positive electrode (e.g., cathode) and a negative electrode (e.g., anode) but replace both the polymer separator and the liquid electrolyte with an ion-conducting material.

Using the implementations described herein, the deposited lithium metal, either single-sided or dual-sided, can be protected during winding and unwinding of the reels downstream. Deposition of one or more thin ceramic protective films as described herein has several advantages. In certain implementations, the one or more ceramic protective films described herein provide adequate surface protection for shipping, handling, and storage as well as avoiding surface reactions of lithium during device integration. In certain implementations, the one or more ceramic protective films described herein are compatible with lithium ions and reduce impedance for ions to move across. In certain implementations, the one or more ceramic protective films described herein are ion conducting and thus may be incorporated into the formed energy storage device. In certain implementations, the one or more ceramic protective films described herein can also help suppress or eliminate lithium dendrites, especially at high current density operation. In certain implementations, the use of ceramic protective films described herein reduces the complexity of manufacturing systems and is compatible with current manufacturing systems.

FIG. 1 illustrates a schematic cross-sectional view of one implementation of an energy storage device 100 incorporating an anode electrode structure 110 formed according to implementations described herein. The anode electrode structure 110 includes an anode film 170 having the one or more ceramic protective film(s) 180 (e.g., ultra-thin ceramic coating) formed thereon according to one or more implementations described herein. The energy storage device 100 may be a solid-state energy storage device or a lithium-ion based energy storage device. The energy storage device 100, even though shown as a planar structure, may also be formed into a cylinder by rolling the stack of layers; furthermore, other cell configurations (e.g., prismatic cells, button cells, or stacked electrode cells) may be formed. The energy storage device 100 includes the anode electrode structure 110 and a cathode electrode structure 120, optionally with a solid-electrolyte film 130 positioned therebetween. In certain implementations where the energy storage device 100 is a Li-ion energy storage device, the solid-electrolyte film 130 is replaced with a polymer separator and a liquid electrolyte. The cathode electrode structure 120 includes a cathode current collector 140 and a cathode film 150.

The one or more ceramic protective film(s) 180 include one or more ceramic materials. The ceramic material may be an oxide. In one implementation, the one or more ceramic protective film(s) 180 includes a material selected from, for example, aluminum oxide (Al₂O₃), AlOₓ, AlOₓN_{y}, AlN (aluminum deposited in a nitrogen environment), aluminum hydroxide oxide ((AlO(OH)) (e.g., diaspore ((α-AlO(OH))), boehmite (γ-AlO(OH)), or akdalaite (5Al₂O₃.H₂O)), calcium carbonate (CaCO₃), titanium dioxide (TiO₂), SiS₂, SiPO₄, silicon oxide (SiO₂), zirconium oxide (ZrO₂), hafnium oxide (HfO₂), MgO, TiO₂, Ta₂O₅, Nb₂O₅, LiAlO₂, BaTiO₃, BN, ion-conducting garnet, ion-conducting perovskite, ion-conducting anti-perovskites, porous glass ceramic, and the like, or combinations thereof. In one implementation, the one or more ceramic protective film(s) 180 comprises a combination of AlOₓ and Al₂O₃. In one implementation, the one or more ceramic protective film(s) 180 includes a material selected from the group comprising, consisting of, or consisting essentially of porous aluminum oxide, porous-ZrO₂, porous-HfO₂, porous-SiO₂, porous-MgO, porous-TiO₂, porous-Ta₂O₅, porous-Nb₂O₅, porous-LiAlO₂, porous-BaTiO₃, ion-conducting garnet, anti-ion-conducting perovskites, porous glass dielectric, or combinations thereof. The one or more ceramic protective film(s) 180 is a binder-free dielectric layer. In certain implementations, the one or more ceramic protective film(s) 180 is a porous aluminum oxide layer. In certain implementations, the one or more ceramic protective film(s) 180 are deposited using evaporation techniques as described herein.

In certain implementations, each layer of the one or more ceramic protective film(s) 180 is a coating or a discrete film having a thickness in a range of 1 nanometer to 3,000 nanometers (e.g., in the range of 10 nanometers to 600 nanometers; in the range of 50 nanometers to 100 nanometers; in the range of 50 nanometers to 200 nanometers; in the range of 100 nanometers to 150 nanometers). In certain implementations, each layer of the one or more ceramic protective film(s) 180 is a coating or discrete film having a thickness of 500 nanometers or less (e.g., from about 1 nm to about 400 nm; from about 25 nm to about 300 nm; from about 50 nm to about 200 nm; from about 100 nm to about 150 nm; from about 10 nm to about 80 nm; or from about 30 to about 60 nanometers). In certain implementations, each layer of the one or more ceramic protective film(s) 180 is a coating or discrete film having a thickness of 100 nanometers or less (e.g., from about 5 nanometers to about 100 nanometers; from about 5 nanometers to about 40 nanometers; from about 10 nanometers to about 20 nanometers; or from about 50 nanometers to about 100 nanometers).

In certain implementations, at least one of the one or more ceramic protective film(s) 180 is porous. In certain implementations, at least one of the one or more protective film(s) 180 has nanopores. In certain implementations, at least one of the one or more protective film(s) 180 has a plurality of nanopores that are sized to have an average pore size or diameter less than about 10 nanometers (e.g., from about 1 nanometer to about 10 nanometers; from about 3 nanometers to about 5 nanometers). In another implementation, at least one of the one or more protective film(s) 180 has a plurality of nanopores sized to have an average pore size or

In one implementation, the one or more ceramic protective film(s) 180 has a thickness “T₁” in a range from about 1 nanometer to about 1,000 nanometers, for example, in a range from about 50 nanometers to about 500 nanometers; or in a range from about 50 nanometers to about 200 nanometers.

In certain implementations, the one or more ceramic protective film(s) 180 includes a plurality of dielectric columnar projections. The dielectric columnar shaped projections may have a diameter that expands from the bottom (e.g., where the columnar shaped projection contacts the porous substrate) of the columnar shaped projection to a top of the columnar shaped projection. The dielectric columnar projections typically comprise dielectric grains. Nano-structured contours or channels are typically formed between the dielectric grains.

In certain implementations, the one or more ceramic protective film(s) 180 may comprise one or more of various forms of porosities. In certain implementations, the columnar projections of the one or more ceramic protective film(s) 180 form a nanoporous structure between the columnar projections of ceramic material. The nanoporous structure may have a plurality of nanopores that are sized to have an average pore size or diameter less than about 10 nanometers (e.g., from about 1 nanometer to about 10 nanometers; from about 3 nanometers to about 5 nanometers). The nanoporous structure may have a plurality of nanopores sized to have an average pore size or diameter less than about 5 nanometers. In one implementation, the nanoporous structure has a plurality of nanopores having a diameter ranging from about 1 nanometer to about 20 nanometers (e.g., from about 2 nanometers to about 15 nanometers; or from about 5 nanometers to about 10 nanometers). The nanoporous structure yields a significant increase in the surface area of the one or more ceramic protective film(s) 180. The pores of the nanoporous structure can act as liquid electrolyte reservoir and provides excess surface area for ion-conductivity.

The cathode electrode structure 120 includes the cathode current collector 140 with the cathode film 150 formed on the cathode current collector 140. It should be understood that the cathode electrode structure 120 may include other elements or films.

The current collectors 140, 160, on the cathode film 150 and the anode film 170, respectively, can be identical or different electronic conductors. In certain implementations, at least one of the current collectors 140, 160 is a flexible substrate. The flexible substrate may be a CPP film (i.e., a casting polypropylene film), an OPP film (i.e., an oriented polypropylene film), or a PET film (i.e., an oriented polyethylene terephthalate film). Alternatively, the flexible substrate may be a pre-coated paper, a polypropylene (PP) film, a PEN film, a poly lactase acetate (PLA) film, or a PVC film. Examples of metals that the current collectors 140, 160 may be comprised of include aluminum (Al), copper (Cu), zinc (Zn), nickel (Ni), cobalt (Co), manganese (Mn), chromium (Cr), stainless steel, clad materials, alloys thereof, and a combination thereof. In one implementation, at least one of the current collectors 140, 160 is perforated. In one implementation, at least one of the current collectors 140, 160 includes a polymer substrate (e.g., polyethylene terephthalate (“PET”) coated with a metallic material. In one implementation, the anode current collector 160 is a polymer substrate (e.g., a PET film) coated with copper. In another implementation, the anode current collector 160 is a multi-metal layer on a polymer substrate. The multi-metal layer can be combinations of copper, chromium, nickel, etc. In one implementation, the anode current collector 160 is a multi-layer structure that includes a copper-nickel cladding material. In one implementation, the multi-layer structure includes a first layer of nickel or chromium, a second layer of copper formed on the first layer, and a third layer including nickel, chromium, or both formed on the second layer. In one implementation, the anode current collector 160 is nickel coated copper. Furthermore, current collectors may be of any form factor (e.g., metallic foil, sheet, or plate), shape and micro/macro structure.

Generally, in prismatic cells, tabs are formed of the same material as the current collector and may be formed during fabrication of the stack, or added later. In certain implementations, the current collectors extend beyond the stack and the portions of the current collector extending beyond the stack may be used as tabs. In one implementation, the cathode current collector 140 is aluminum. In another implementation, the cathode current collector 140 comprises aluminum deposited on a polymer substrate (e.g., a PET film). The cathode current collector 140 may have a thickness below 50 μm, more specifically, 5 μm or, even more specifically 2 μm. The cathode current collector 140 may have a thickness from about 0.5 μm to about 20 μm (e.g., from about 1 μm to about 10 μm; from about 2 μm to about 8 μm; or from about 5 μm to about 10 μm). In one implementation, the anode current collector 160 is copper. In one implementation, the anode current collector 160 is stainless steel. In one implementation, the anode current collector 160 has a thickness below 50 μm more specifically, 5 μm or, even more specifically 2 μm. In one implementation, the anode current collector 160 has a thickness from about 0.5 μm to about 20 μm (e.g., from about 1 μm to about 10 μm; from about 2 μm to about 8 μm; from about 6 μm to about 12 μm; or from about 5 μm to about 10 μm).

The cathode film 150 or cathode may be any material compatible with the anode and may include an intercalation compound, an insertion compound, or an electrochemically active polymer. Suitable intercalation materials include, for example, lithium-containing metal oxides, MoS₂, FeS₂, BiF₃, Fe₂OF₄, MnO₂, TiS₂, NbSe₃, LiCoO₂, LiNiO₂, LiMnO₂, LiMn₂O₄, V₆O₁₃ and V₂O₅. Suitable polymers include, for example, polyacetylene, polypyrrole, polyaniline, and polythiophene. The cathode film 150 or cathode may be made from a layered oxide, such as lithium cobalt oxide, an olivine, such as lithium iron phosphate, or a spinel, such as lithium manganese oxide. Exemplary lithium-containing oxides may be layered, such as lithium cobalt oxide (LiCoO₂), or mixed metal oxides, such as LiNiₓCo₁₋₂ₓMnO₂, LiNiMnCoO₂ (“NMC”), LiNi_{0.5}Mn_{1.5}O₄, Li(Ni_{0.8}Co_{0.15}Al_{0.05})O₂, LiMn₂O₄, and doped lithium rich layered-layered materials, wherein x is zero or a non-zero number. Exemplary phosphates may be iron olivine (LiFePO₄) and it is variants (such as LiFe₍₁₋ₓ₎MgₓPO₄), LiMoPO₄, LiCoPO₄, LiNiPO₄, Li₃V₂(PO₄)₃, LiVOPO₄, LiMP₂O₇, or LiFe_{1.5}P₂O₇, wherein x is zero or a non-zero number. Exemplary fluorophosphates may be LiVPO₄F, LiAIPO₄F, Li₅V(PO₄)₂F₂, Li₅Cr(PO₄)₂F₂, Li₂CoPO₄F, or Li₂NiPO₄F. Exemplary silicates may be Li₂FeSiO₄, Li₂MnSiO₄, or Li₂VOSiO₄. An exemplary non-lithium compound is Na₅V₂(PO₄)₂F₃.

The anode electrode structure 110 includes the anode current collector 160 with the anode film 170 formed on the anode current collector 160. The anode electrode structure 110 comprises the one or more ceramic protective film(s) 180.

In some implementations, the anode film 170 is constructed from lithium metal, lithium metal foil or a lithium alloy foil (e.g. lithium aluminum alloys), or a mixture of a lithium metal and/or lithium alloy and materials such as carbon (e.g. coke, graphite), nickel, copper, tin, indium, silicon, oxides thereof, or a combination thereof. The anode film 170 typically comprises intercalation compounds containing lithium or insertion compounds containing lithium. In certain implementations, the anode film is a lithium metal film. In certain implementations, wherein the anode film 170 comprises lithium metal, the lithium metal may be deposited using the methods described herein.

In some implementations, the anode film 170 is constructed from graphite, silicon, or a combination thereof. The anode film 170 can be constructed from a carbonaceous material, for example, natural graphite or artificial graphite, partially graphitized or amorphous carbon, petroleum, coke, needle coke, and various mesophases, silicon-containing graphite, silicon, nickel, copper, tin, indium, aluminum, silicon, oxides thereof, combinations thereof, or a mixture of a lithium metal and/or lithium alloy and materials such as carbon, for example, coke or graphite, nickel, copper, tin, indium, aluminum, silicon, oxides thereof, or combinations thereof. In one example, the anode film 170 is constructed from silicon-graphite. In another example, the anode film 170 is constructed from graphite. In yet another example, the anode film 170 is constructed from silicon.

In some implementations where the anode film 170 is constructed from graphite, silicon, or silicon-graphite, the anode film 170 has a layer of lithium formed on the surface of the anode film 170. The layer of lithium metal can have a thickness from about 20 microns to about 50 microns. The layer of lithium can be a pre-lithiation layer.

In one implementation, the anode film 170 has a thickness from about 10 μm to about 200 μm (e.g., from about 1 μm to about 100 μm; from about 10 μm to about 30 μm; from about 20 μm to about 30 μm; from about 1 μm to about 20 μm; or from about 50 μm to about 100 μm).

In at least one aspect, the solid-electrolyte film 130 is a lithium-ion conducting material. In at least one aspect, the lithium-ion conducting material is a lithium-ion conducting ceramic or a lithium-ion conducting glass. In at least one implementation, the Li-ion conducting material is comprised of one or more of LiPON, doped variants of either crystalline or amorphous phases of Li₇La₃Zr₂O₁₂, doped anti-perovskite compositions, argyrodite compositions (e.g., Li₆PS₅Br, Li₆PS₅Cl, Li₇PS₆, Li₆PS₅I, Li₆PO₅Cl), lithium-sulfur-phosphorous materials, Li₂S—P₂S₅, Li₁₀eP₂S₁₂, and Li₃PS₄, lithium phosphate glasses, (1-x)LiI-(x)Li₄SnS₄, xLiI-(1-x)Li₄SnS₄, mixed sulfide and oxide electrolytes (crystalline LLZO, amorphous (1-x)LiI-(x)Li₄SnS₄ mixture, amorphous xLiI-(1-x)Li₄SnS₄), Li₃S(BF₄)_{0.5}Cl_{0.5}, Li₄Ti₅O₁₂, lithium doped lanthanum titanate (LATP), Li₂₊₂ₓZn₁₋ₓGeO₄, LiM₂(PO₄)₃ where M=Ti, Ge, Hf, for example. In at least one aspect, x is between 0 and 1 (e.g., 0.1, 0.2, 0.3, 0.4, 0.5, 0.6, 0.7, 0.8, and 0.9).

In another implementation where the solid-electrolyte film 130 is replaced with a separator, the separator is a porous polymeric ion-conducting polymeric substrate. In one implementation, the porous polymeric substrate is a multi-layer polymeric substrate. In certain implementations, the separator includes any commercially available polymeric microporous membranes (e.g., single or multi-ply), for example, those products produced by Polypore (Celgard® LLC. of Charlotte, N.C.), Toray Tonen (Battery separator film (BSF)), SK Energy (lithium ion battery separator (LiBS), Evonik industries (SEPARION® ceramic separator membrane), Asahi Kasei (Hipore™ polyolefin flat film membrane), and DuPont (Energain®). In certain implementations, the porous polymeric substrate has a porosity in the range of 20 to 80% (e.g., in the range of 28 to 60%). The porous polymeric substrate may have an average pore size in the range of 0.02 to 5 microns (e.g., 0.08 to 2 microns). In certain implementations, the porous polymeric substrate has a Gurley Number in the range of 15 to 150 seconds. The porous polymeric substrate may comprise a polyolefin polymer. Examples of suitable polyolefin polymers include polypropylene, polyethylene, or combinations thereof. In at least one aspect, the porous polymeric substrate is a polyolefinic membrane. In some aspect, the polyolefinic membrane is a polyethylene membrane or a polypropylene membrane.

In at least one aspect, the porous polymeric substrate has a thickness “Ti” in a range from about 1 micron to about 50 microns, for example, in a range from about 3 microns to about 25 microns; in a range from about 7 microns to about 12 microns; or in a range from about 14 microns to about 18 microns.

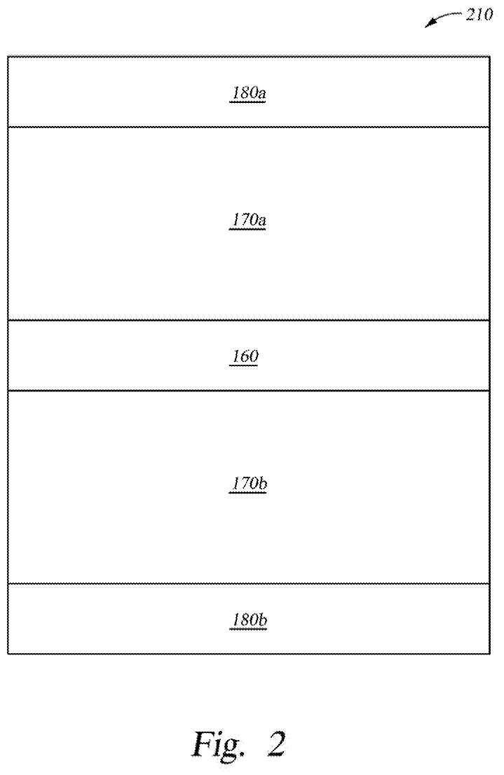

FIG. 2 illustrates a cross-sectional view of one implementation of a dual-sided anode electrode structure 210 formed according to one or more implementations described herein. The dual-sided anode electrode structure 210 comprises the anode current collector 160 with the anode film 170a, 170b (collectively 170) formed on opposing sides of the anode current collector 160. The dual-sided anode electrode structure 210 further comprises one or more ceramic protective film(s) 180a, 180b (collectively 180) formed on anode films 170a, 170b respectively.

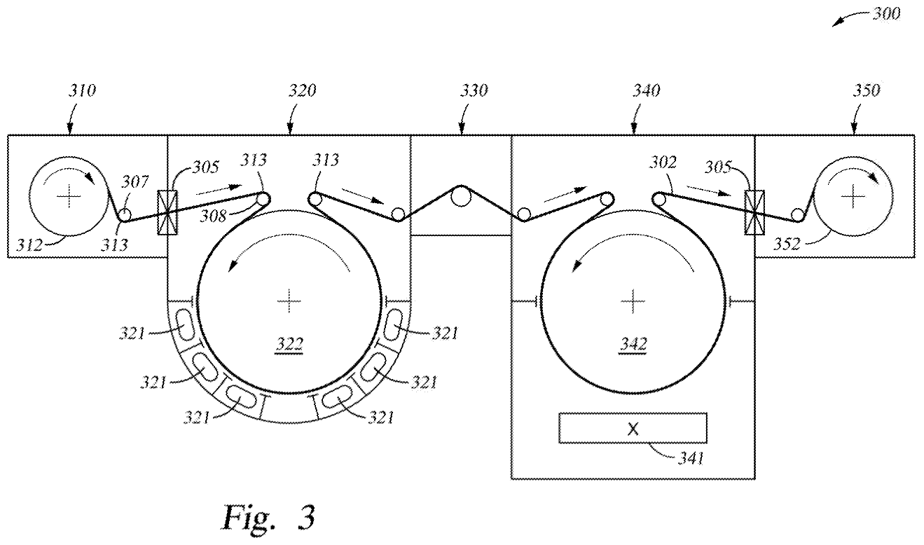

FIG. 3 illustrates a schematic side view of a deposition apparatus 300 operable to coat one or more flexible substrates 302, for example, the anode current collector 160, according to one or more implementations described herein. The one or more flexible substrates 302 may be, for example, the anode current collector 160, according to one or more implementations described herein. The deposition apparatus 300 includes a plurality of vacuum chambers that can be evacuated to a pressure below atmospheric pressure. The deposition apparatus 300 depicted in FIG. 3 includes a first spool chamber 310, a first deposition chamber 320 arranged downstream from the first spool chamber 310, a second deposition chamber 340 arranged downstream from the first deposition chamber 320, and a second spool chamber 350 arranged downstream from the second deposition chamber 340. The first deposition chamber 320 is operable to deposit a lithium metal anode, for example, the lithium anode film 170. The second deposition chamber 340 is operable to deposit a ceramic protective film, for example, the one or more ceramic protective film(s) 180.

The first spool chamber 310 may be considered as a vacuum chamber configured for housing a storage spool with a flexible substrate wound thereon, and the second spool chamber 350 may be considered as a vacuum chamber configured for housing a wind-up spool operable to wind the coated flexible substrate thereon after deposition. The deposition apparatus 300 may be configured such that the flexible substrate 302 can be guided from the first spool chamber 310 to the second spool chamber 350 along a substrate transportation path, wherein the substrate transportation path may lead through the first deposition chamber 320 and through the second deposition chamber 340. The flexible substrate 302 can be coated with the lithium metal layers in the first deposition chamber 320 and ceramic protective layers in the second deposition chamber 340. A roller assembly comprising a plurality of rolls or rollers can be provided for transporting the substrate along the substrate transportation path, wherein two or more rollers, five or more rollers, or ten or more rollers of the roller assembly may be arranged between the storage spool and the wind-up spool.

According to certain implementations described herein, the substrate transportation path may be partially convex and partially concave. In other words, the substrate transportation path is partially curved to the right and partially curved to the left such that some guiding rollers contact a first main surface of the flexible substrate and some guiding roller contact a second main surface of the flexible substrate opposite to the first main surface. For example, the first guiding roller 307 in FIG. 3 contacts a second main surface of the flexible substrate and the flexible substrate is bent to the left while being guided by the first guiding roller 307 (“convex” section of the substrate transportation path). The second guiding roller 308 in FIG. 3 contacts a first main surface of the flexible substrate and the flexible substrate is bent to the right while being guided by the second guiding roller 308 (“concave” section of the substrate transportation path). A compact deposition apparatus may be provided that may be suitable also for two-side deposition because the substrate transportation path changes directions several times between the first spool chamber and the second spool chamber in concave section, i.e. in sections where the first main surface of the substrate contacts a support surface, and in convex sections, i.e. in sections where the second main surface of the substrate contacts a support surface.

The terms “upstream from” and “downstream from” as used herein may refer to the position of the respective chamber or of the respective component with respect to another chamber or component along the substrate transportation path. For example, during operation, the substrate is guided through the first deposition chamber 320 and subsequently guided through the second deposition chamber 340 along the substrate transportation path via the roller assembly. Accordingly, the second deposition chamber 340 is arranged downstream from the first deposition chamber 320, and the first deposition chamber 320 is arranged upstream from the second deposition chamber 340. When, during operation, the substrate is first guided by or transported past a first roller or a first component and subsequently guided by or transported past a second roller or a second component, the second roller or second component is arranged downstream from the first roller or first component.

The first spool chamber 310 is configured to accommodate a storage spool 312, wherein the storage spool 312 may be provided with the flexible substrate 302 wound thereon. During operation, the flexible substrate 302 can be unwound from the storage spool 312 and transported along the substrate transportation path from the first spool chamber toward the first deposition chamber. The term “storage spool”0 as used herein may be understood as a roll on which a flexible substrate to be coated is stored. Accordingly, the term “wind-up spool” as used herein may be understood as a roll adapted for receiving the coated flexible substrate. The term “storage spool” may also be referred to as a “supply roll” herein, and the term “wind-up spool” may also be referred to as a “take-up roll” herein.

In certain implementations, which may be combined with other implementations described herein, the flexible substrate 302 may be guided through openings, e.g., slits, in the walls separating the vacuum chambers from each other, respectively. For example, a slit in the wall between two vacuum chambers may be adapted for guiding the substrate from one vacuum chamber to another vacuum chamber, respectively. In certain implementations, the opening may be provided with a sealing device in order to separate, at least substantially, the pressure conditions of the two vacuum chambers linked by the opening. For instance, if the chambers being linked by the opening provide different pressure conditions, the opening in the wall may be designed so as to maintain the respective pressure in the chambers.

According to implementations described herein, at least one gap sluice or load-lock valve may be provided for separating two adjacent vacuum chambers from each other, e.g. for separating the first spool chamber from the vacuum chamber arranged downstream therefrom. The at least one gap sluice may be configured such that the flexible substrate can move therethrough and the gap sluice can be opened and closed for providing a vacuum seal. Thus, for instance, the first spool chamber 310 can be vented while the first deposition chamber 320 can be maintained under technical vacuum.

For example, a sealing device 305 arranged between the first spool chamber and the first deposition chamber 320 is schematically indicated in FIG. 3. However, it is to be understood that further sealing devices providing a corresponding functionality may be provided between other adjacent vacuum chambers, e.g. between the second deposition chamber 340 and the second spool chamber 350.

The sealing device 305 may include an inflatable seal configured to press the substrate against a flat sealing surface. Accordingly, the opening in the wall between the first spool chamber 310 and the first deposition chamber 320 can be sealed, even when the flexible substrate may be present in the opening. Removal of the flexible substrate may not be necessary for closing or opening the sealing device. Yet, also other means for selectively opening and closing a gap sluice can be utilized, wherein opening and closing, i.e. having an open substrate path and a vacuum seal, can be conducted while the substrate is inserted. The gap sluice for closing the vacuum seal while the substrate is inserted allows for particularly easy exchange of the substrate, as the substrate from the new roll can be attached to the substrate from the previous roll.

Although the sealing devices, slits, openings or gap sluices are described with respect to guiding the flexible substrate from the first spool chamber to the following vacuum chamber, the sealing devices, slits, openings or gap sluices as described herein may also be used between other chambers or parts of the deposition apparatus.

The first deposition chamber 320 may include a first coating drum 322 configured for guiding the flexible substrate 302 past a first plurality of deposition units 321. The first coating drum 322 may be rotatable around a rotation axis A. The coating drum may include a curved substrate support surface, e.g. an outer surface of the first coating drum 322, on which the flexible surface can be guided past the first plurality of deposition units 321. While guiding the flexible substrate past the first plurality of deposition units 321, the flexible substrate may be in direct contact with the substrate support surface of the first coating drum, which may be cooled. The temperature of the flexible substrate may be reduced during deposition, when the flexible substrate is in direct thermal contact with the first coating drum.

The flexible substrate 302 may be coated with one or more thin layers, for example, thin layers of lithium, by the first plurality of deposition units 321. For example, the deposition units of the first plurality of deposition units 321 may be arranged in a circumferential direction around the first coating drum 322, as is schematically depicted in FIG. 3. The first deposition chamber 320 may include two or more deposition units arranged next to each other along the substrate transportation path. A first main surface of the flexible substrate 302 may be coated, while a second main surface of the flexible substrate opposite to the first main surface, i.e. the rear surface of the flexible substrate, may be in contact with the curved substrate support surface of the first coating drum.

As the first coating drum 322 rotates, the flexible substrate is guided past the deposition units, which face toward the curved substrate support surface of the first coating drum so that the first main surface of the flexible substrate can be coated while being moved past the deposition units at a predetermined speed.

In certain implementations, one or more rollers, e.g. guiding rollers, of the roller assembly may be arranged between the storage spool 312 and the first coating drum 322 and/or downstream from the first coating drum 322. For example, in the implementation shown in FIG. 3, two guiding rollers 313 are provided between the storage spool 312 and the first coating drum 322, wherein at least one guiding roller may be arranged in the first spool chamber and at least one guiding roller may be arranged in the first deposition chamber upstream from the first coating drum 322. In certain implementations, three, four, five or more, particularly eight or more guiding rollers are provided between the storage spool and the first coating drum. The guiding rollers may be active or passive rollers.

An “active” roller or roll as used herein may be understood as a roller that is provided with a drive or a motor for actively moving or rotating the respective roller. For example, an active roller may be adjusted to provide a predetermined torque or a predetermined rotational speed. Typically, the storage spool 312 and the wind-up spool 352 may be provided as active rollers. In certain implementations, the coating drum may be configured as an active roller. Further, active rollers can be configured as substrate tensioning rollers configured for tensioning the substrate with a predetermined tensioning force during operation. A “passive” roller as used herein may be understood as a roller or roll that is not provided with a drive for actively moving or rotating the passive roller. The passive roller may be rotated by the frictional force of the flexible substrate that may be in direct contact with an outer roller surface during operation.

In the present disclosure, a “roll” or “roller” may be understood as a device, which provides a surface, with which the flexible substrate 302 or part of the flexible substrate 302 may come in contact during transport of the flexible substrate 302 along the substrate transportation path in the deposition apparatus. At least a part of the roller as referred to herein may include a circular-like shape for contacting the flexible substrate 302 before or after deposition. The substantially cylindrical shape may be formed about a straight longitudinal axis. According to some implementations, a roller may be a guiding roller adapted to guide a substrate while the substrate is transported, e.g., during a deposition process or while the substrate is present in the deposition apparatus. The roller may be configured as a spreader roller, i.e. an active roller adapted for providing a defined tension for the flexible substrate, a processing roller, e.g., a coating drum, for supporting the flexible substrate while being coated, a deflecting roller for deflecting the substrate along the curved substrate transportation path, an adjusting roller, a storage spool, a wind-up spool etc.

In certain implementations, at least one deflecting roller may be configured for deflecting the flexible substrate in a clockwise direction, and at least one deflecting roller may be configured for deflecting the flexible substrate in a counterclockwise direction. For example, in the implementations shown in FIG. 3, a first guiding roller 307 deflects the flexible substrate in a counterclockwise direction (i.e. the flexible substrate is bent to the left when moved along the substrate transportation path), and a second guiding roller 308 deflects the flexible substrate in a clockwise direction (i.e. the flexible substrate is bent to the right when moved along the substrate transportation path). Therein, the first guiding roller 307 may rotate in a counterclockwise direction, and the second guiding roller 308 may rotate in a clockwise direction. A partially convex and partially concave substrate transportation path can be provided. Guiding rollers rotating in a clockwise direction during transport of the flexible substrate may be referred to herein as “clockwise rotating rollers” and rollers rotating in a counterclockwise direction during transport of the flexible substrate may be referred to herein as “counterclockwise rotating rollers.”

In certain implementations, at least one guiding roller, e.g. the first guiding roller 307, contacts the first main surface of the substrate, and at least one guiding roller, e.g., the second guiding roller 308, contacts the second main surface of the substrate, i.e. the surface opposite to the first main surface.

According to some implementations, the rollers as described herein may be mounted to low friction roller bearings, particularly with a dual bearing roller architecture. Accordingly, roller parallelism of the transportation arrangement as described herein can be achieved and a transverse substrate “wandering” during substrate transport may be eliminated.

In certain implementations, a guiding roller, which guides the flexible substrate along the substrate transportation path, may also be configured for conducting a tension measurement. According to typical implementations, at least one tension measurement roller, e.g., a passive roller, may be provided in the deposition apparatus. Beneficially, one, two or more tension measurement rollers on both sides of the first coating drum and/or on both sides of the second coating drum may be provided which allow for tension measurements on the winding side and on the unwinding side of the coating drum. In particular, the tension measurement rollers may be configured for measuring the tension of the flexible substrate. Accordingly, the substrate transport can be better controlled, the pressure of the substrate on the coating drum can be controlled and/or damage to the substrate can be reduced or avoided.

The second deposition chamber 340 may be arranged downstream from the first deposition chamber 320. Accordingly, the flexible substrate 302 may enter the second deposition chamber 340, after the flexible substrate 302 has been guided by the first coating drum 322 past the first plurality of deposition units 321. In certain implementations, the second deposition chamber 340 may be arranged directly downstream from the first deposition chamber 320. In other implementations, one or more further vacuum chambers, e.g., a connection chamber 330, may be arranged between the first deposition chamber 320 and the second deposition chamber 340.

The second deposition chamber 340 includes a second coating drum 342 configured for guiding the flexible substrate past a second deposition unit 341. The flexible substrate 302 may be coated with a thin ceramic layer by the second deposition unit 341 in the second deposition chamber 340. For example, the second deposition unit 341 is positioned along the substrate transportation path adjacent to the second coating drum 342, as is schematically depicted in FIG. 3. The flexible substrate 302 may be coated, while the rear surface of the flexible substrate 302 is in direct contact with a curved substrate support surface of the second coating drum 342.

As the second coating drum 342 rotates, the flexible substrate 302 is guided past the second deposition unit 341, which face toward the curved substrate support surface of the second coating drum 342 so that the flexible substrate can be coated while being moved past the second deposition unit 341 at a predetermined speed.

In certain implementations, which can be combined with other implementations described herein, both the first plurality of deposition units 321 and the second deposition unit 341 may be configured operable to coat the first main surface of the flexible substrate 302. In other words, a lithium metal layer of the stack of layers is deposited on the first main surface of the flexible substrate 302 by the first plurality of deposition units 321 in the first deposition chamber 320, and a ceramic protective layer of the stack of layers is deposited on top of the lithium metal layer by the second deposition unit 341 in the second deposition chamber 340. Accordingly, only the first main surface of the flexible substrate 302 is coated with a stack of layers during transport of the flexible substrate 302 along the substrate transportation path through the deposition apparatus 300.

For also coating the second main surface of the flexible substrate 302, the flexible substrate 302 with the coated first main surface may be loaded again into the first spool chamber 310 and transported through the deposition apparatus in an inverted orientation. In the “inverted orientation” as used herein, the second main surface of the flexible substrate 302, i.e. the other main surface as compared to the first pass of the flexible substrate 302 through the deposition apparatus 300, is directed toward the first plurality of deposition units 321 and/or toward the second deposition unit 341 during transport of the flexible substrate 302 along the substrate transportation path. Accordingly, two-side deposition on the flexible substrate 302 is possible by guiding the same flexible substrate 302 two times through the deposition apparatus 300. In certain implementations, a first stack of layers is deposited on the first main surface of the flexible substrate 302 on the first pass through the deposition apparatus 300, and a second stack of layers is deposited on the second main surface of the flexible substrate 302 on the second pass through the deposition apparatus 300. The first stack of layers and the second stack of layers may have a corresponding thickness and/or a corresponding material sequence. In certain implementations, the flexible substrate 302 with two coated main surfaces may be essentially symmetrical with respect to the central plane of the flexible substrate 302.

In certain implementations, which may be combined with other implementations described herein, at least one of the first coating drum 322 and the second coating drum 342 may be actively driven. In other words, a first drive may be provided for rotating the first coating drum 322 and/or a second drive may be provided for rotating the second coating drum 342.

In certain implementations, one or more guiding rollers 313 may be arranged downstream from the first coating drum 322 and upstream from the second coating drum 342. For example, at least one guiding roller may be arranged in the first deposition chamber 320 downstream from the first coating drum 322 for guiding the flexible substrate 302 toward the vacuum chamber arranged downstream from the first deposition chamber 320, or at least one guiding roller may be arranged in the second deposition chamber 340 upstream from the second coating drum 342 for guiding the flexible roller in a direction essentially tangential to the substrate support surface of the second coating drum 342, in order to smoothly guide the flexible substrate onto the second coating drum 342. In certain implementations, three or more, particularly five or more, more particularly seven or more guiding rollers are provided between the first coating drum and the second coating drum. At least one or more of these guiding rollers may have functions that are discussed below in further detail.

The second spool chamber 350 may be arranged directly downstream from the second deposition chamber 340. In certain implementations, one or more vacuum chambers may be arranged between the second deposition chamber 340 and the second spool chamber 350. The second spool chamber 350 may be configured for housing a wind-up spool 352 operable to wind the flexible substrate 302 thereon after deposition. Sealing devices may be provided in the walls between the vacuum chambers, respectively, and particularly in a wall which separates the second spool chamber 350 from the deposition chambers. For example, in the implementations shown in FIG. 3, a sealing device 305 is provided between the second deposition chamber 340 and the second spool chamber 350. The sealing device 305 may include an inflatable seal configured to press the substrate against a sealing surface. Accordingly, the opening in the wall between the second deposition chamber 340 and the second spool chamber 350 can be sealed, even when the flexible substrate 302 may be present in the opening. Removal of the flexible substrate 302 may not be necessary for closing or opening the sealing device.

In certain implementations, which may be combined with other implementations described herein, a wind-up spool drive may be provided for rotating the wind-up spool 352 for winding the flexible substrate 302 thereon. In other words, the wind-up spool 352 may be an active roller.

The second spool chamber 350 may be configured as a load-lock chamber. Therein, the second spool chamber 350 may be configured such that the wind-up spool 352 with the coated flexible substrate 302 wound thereon can be unloaded from the second spool chamber 350, while the second spool chamber 350 may be flooded. For flooding of the second spool chamber 350, a passage between the second spool chamber 350 and the vacuum chamber arranged upstream from the second spool chamber 350 may be sealed, e.g. via the sealing device 305. Accordingly, other vacuum chambers of the deposition apparatus, and particularly the deposition chambers, can be maintained in an evacuated state during an exchange of a wind-up spool with a new wind-up spool. In certain implementations, the second spool chamber 350 may include a gap sluice or load lock valve, e.g. including a sealing device, e.g. for closing and opening a passage or slit between the second deposition chamber 340 and the second spool chamber 350. The flexible substrate 302 may remain in the opening in a sealed state of the sealing device.

During the deposition, the first deposition chamber 320 and/or the second deposition chamber 340 may be under medium vacuum or under high vacuum, e.g. at a pressure between 1×10⁻² mbar and 1×10⁻⁴ mbar, e.g. when sputter sources are used. The pressure inside the deposition units may be higher than the pressure in a main volume of the deposition chambers, e.g. by an order of magnitude. For example, the pressure inside the sputter deposition units during sputter deposition may be about 5×10⁻³ mbar. The pressure in the first spool chamber 310 and in the second spool chamber 350 may be higher than the pressure in the deposition chambers during deposition, e.g. by one or two orders of magnitude. For example, the background pressure in the first spool chamber 310 and/or in the second spool chamber 350 may be between 10⁻¹ mbar and 10⁻³ mbar. One or more vacuum control units may be provided, e.g. in at least one vacuum chamber and/or in at least one deposition unit.

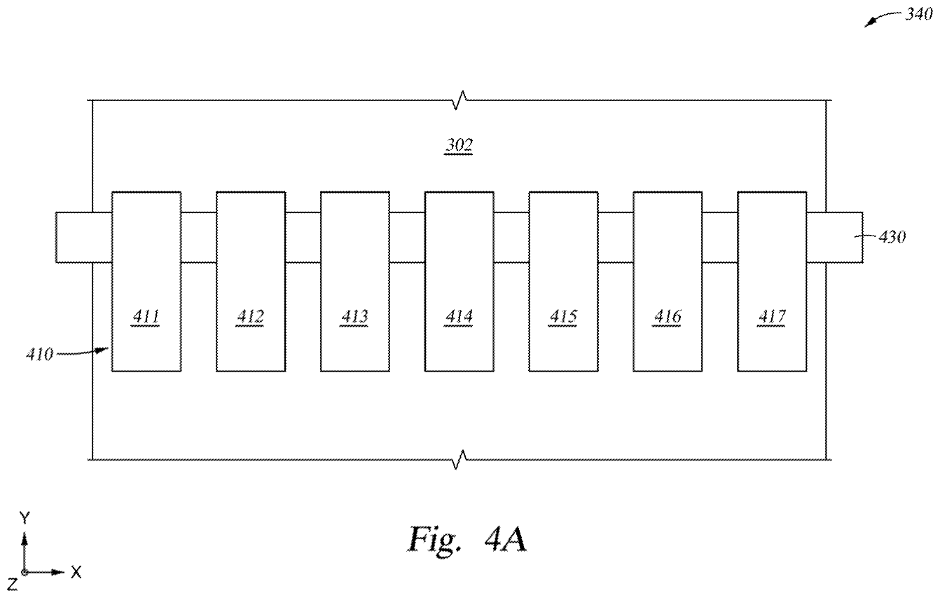

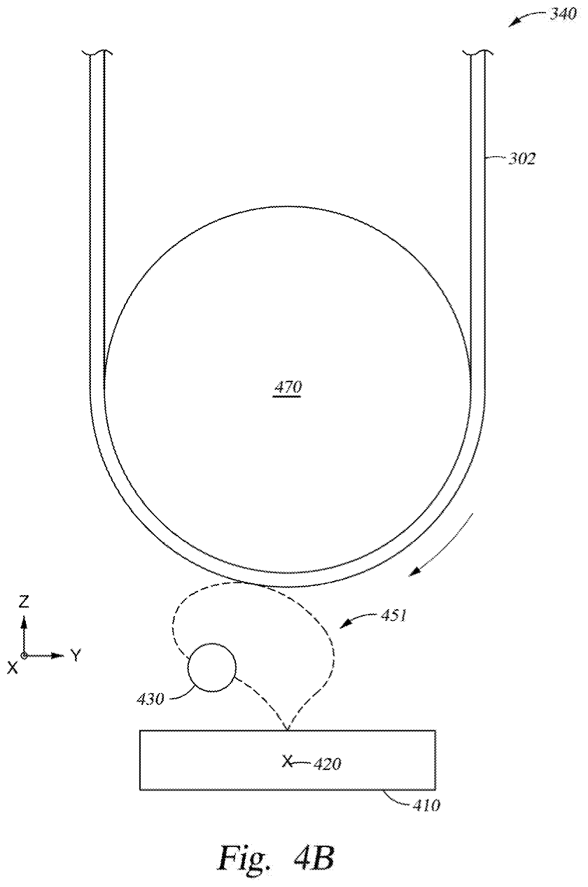

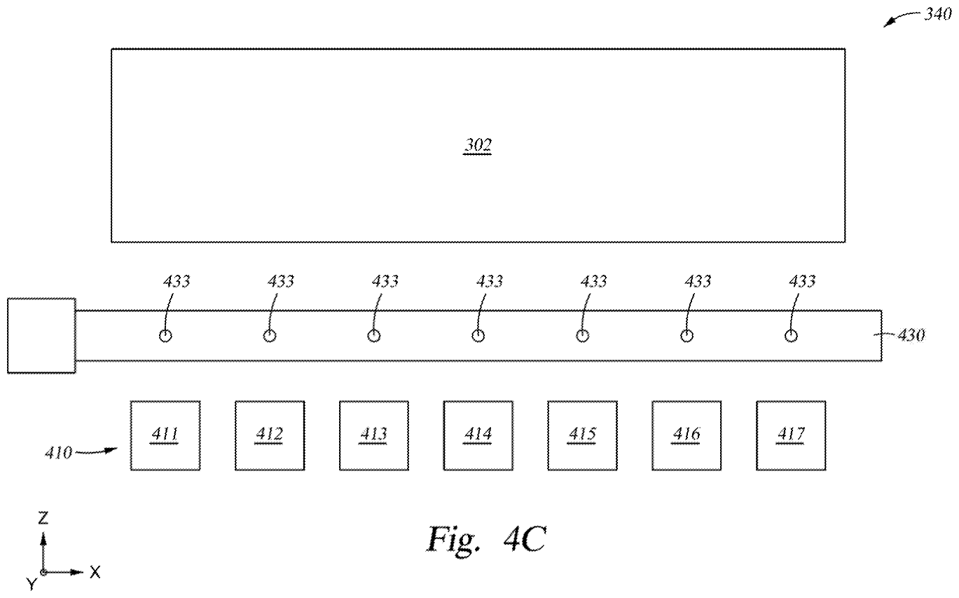

The second deposition chamber 340 will be described in additional detail with reference to FIGS. 4A-4C. In certain implementations, as depicted in FIGS. 4A-4C, the second deposition chamber 340 is an evaporation apparatus.

FIG. 4A illustrates a schematic top view of one example of the second deposition chamber 340 for forming a ceramic-coated separator according to implementations described herein. FIG. 4B illustrates a schematic front view of the second deposition chamber 340 shown in FIG. 4A. FIG. 4C illustrates a schematic top view of the second deposition chamber 340 shown in FIG. 4A. The second deposition chamber 340 may be used to form the ceramic protective film 180 as described herein. As shown in FIGS. 4A-4C, the second deposition unit 341 is an evaporation apparatus. The second deposition chamber 340 may be used to perform the method 500 as described herein. In the second deposition chamber 340 depicted in FIG. 4, the second deposition unit is an evaporation crucible. For example, the second deposition chamber 340 may be used to deposit an ultra-thin ceramic coating, for example, the one or more ceramic protective film(s) 180, over a flexible conductive substrate, for example, the flexible substrate 302, having a lithium metal film, for example, the anode film 170, formed thereon.

In certain implementations, as shown in FIGS. 4A and 4B, the second deposition chamber 340 includes a first set 410 of evaporation crucibles aligned in a first line 420 along a first direction, e.g. along the x-direction shown in FIG. 4A, for generating a cloud 451 of evaporated material to be deposited on a flexible substrate, such as the flexible substrate 302. In one implementation, the flexible substrate 302 includes an anode current collector, for example, the anode current collector 160, having a lithium metal film, for example, the anode film 170, formed thereon.

With exemplary reference to FIG. 1, typically the flexible substrate 302 moves in the y-direction during the deposition process. The first set 410 of evaporation crucibles shown in FIG. 4A includes crucibles 411 to 417. Further, as exemplarily shown in FIG. 4C, the second deposition chamber 340 includes a gas supply pipe 430 extending in the first direction and being arranged between the first set 410 of evaporation crucibles and a processing drum 470. As shown in FIG. 4C, typically the gas supply pipe 430 includes a plurality of outlets 433 for providing a gas supply directed into the cloud 451 of evaporated material. Further, as indicated by the double arrows in FIG. 4B, the evaporation apparatus is configured such that a position of the plurality of outlets is adjustable for changing a position of the gas supply directed into the cloud 451 of evaporated material.

Accordingly, it is to be understood that the second deposition chamber 340 as described herein may be an evaporation apparatus for a reactive evaporation process. In some implementations, the herein described crucibles may be adapted for providing evaporated material on the substrate to be coated. For example, the crucibles may provide one component of the material to be deposited as a layer on the substrate. In particular, the crucibles described herein may include a metal, e.g. aluminum, which is evaporated in the crucibles. Further, the evaporated material from the crucibles may react with a further component, e.g. a reactive gas such as oxygen and/or a plasma such as an oxygen-containing plasma, in the evaporation apparatus for forming a ceramic-containing layer as described herein on the flexible substrate. Accordingly, the aluminum from the crucibles together with the oxygen and/or oxygen-containing plasma as described herein may form a layer of AlOₓ, Al₂O₃, and/or a mixed layer of Al₂O₃/AlOₓ on the flexible substrate in the evaporation apparatus according to implementations described herein. In view of the implementations described herein, the skilled person understands that any material, specifically any metal, may be used as material in the crucibles as long as the vapor pressure of the material may be achieved by thermal evaporation.

During processing, the flexible substrate 302 is subjected to the material evaporated by the first set 410 of evaporation crucibles as indicated by the cloud 451 of evaporated material, as exemplarily shown in FIG. 4B. Further, during processing, a gas supply and/or plasma is directed into the cloud 451 of evaporated material, such that a portion of the evaporated material may react with the supplied gas and/or plasma. Accordingly, the flexible substrate 302 is further subjected to evaporated material, which has been reacted with the supplied gas and/or plasma such that during processing, the flexible substrate 302 is coated with a layer including the material evaporated by the crucibles and the supplied gas and/or plasma, for example, in the form of reactive products of the components provided by the crucible and the gas supply pipe.

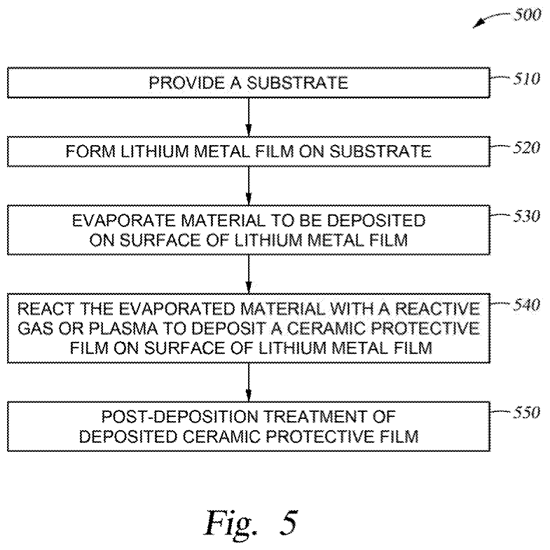

FIG. 5 illustrates a process flow chart 500 summarizing one implementation of a method for forming an electrode structure according to implementations described herein. At operation 510, a substrate is provided. In one implementation, the substrate is a continuous sheet of material, such as the flexible substrate 302 as shown in FIG. 3. In one implementation, the flexible substrate is the anode current collector 160. Examples of metals that the substrate may be comprised of include aluminum (Al), copper (Cu), zinc (Zn), nickel (Ni), cobalt (Co), manganese (Mn), chromium (Cr), stainless steel, clad materials, alloys thereof, or a combination thereof. In one implementation, the substrate is copper material. In one implementation, the substrate is a stainless steel material. In one implementation, the substrate is perforated. Furthermore, the substrate may be of any form factor (e.g., metallic foil, sheet, or plate), shape and micro/macro structure.

In some implementations, the substrate is exposed to a pretreatment process, which includes at least one of a plasma treatment or corona discharge process to remove organic materials from the exposed surfaces of the current collector. The pretreatment process is performed prior to film deposition on the substrate.

At operation 520, a lithium metal film is formed on the substrate. In one implementation, the lithium metal film is the anode film 170 and the substrate is the anode current collector 160. In one implementation, the lithium metal film is formed on a copper current collector. In some implementations, if an anode film is already present on the substrate, the lithium metal film is formed on the anode film. If the anode film 170 is not present, the lithium metal film may be formed directly on the substrate. Any suitable lithium metal film deposition process for depositing thin films of lithium metal may be used to deposit the thin film of lithium metal. Deposition of the thin film of lithium metal may be by PVD processes, such as evaporation (e.g., thermal evaporation or e-beam), sputtering, a slot-die process, a transfer process, or a three-dimensional lithium printing process. The chamber for depositing the thin film of lithium metal may include a PVD system, such as an electron-beam evaporator, a thermal evaporator, or a sputtering system, a thin film transfer system (including large area pattern printing systems such as gravure printing systems) or a slot-die deposition system.

At operation 530, the material to be deposited on a surface of the lithium metal film is exposed to an evaporation process to evaporate the material to be deposited in a processing region. In one implementation, the material to be evaporated is a metal or a metal oxide. In one implementation, the material to be evaporated is chosen from the group of aluminum (Al), zirconium (Zr), hafnium (Hf), niobium (Nb), tantalum (Ta), titanium (Ti), yttrium (Y), lanthanum (La), silicon (Si), boron (B), silver (Ag), chromium (Cr), copper (Cu), indium (In), iron (Fe), magnesium (Mg), calcium (Ca), strontium (Sr), barium (Ba), nickel (Ni), tin (Sn), ytterbium (Yb), lithium (Li), calcium (Ca) or combinations thereof. In another implementation, the material to be evaporated is chosen from the group of zirconium oxide, hafnium oxide, silicon oxide, magnesium oxide, titanium oxide, tantalum oxide, niobium oxide, lithium aluminum oxide, barium titanium oxide, or combinations thereof. In one implementation, the material to be deposited is a metal such as aluminum. Further, the evaporation material may also be an alloy of two or more metals. The evaporation material is the material that is evaporated during the evaporation and with which the lithium metal film is coated. The material to be deposited (e.g., aluminum) can be provided in a crucible such as, for example, evaporation crucibles 411-417. The material to be deposited, for example, can be evaporated by thermal evaporation techniques or by electron beam evaporation techniques. In another implementation, the material to be deposited is deposited using chemical vapor deposition (CVD) or atomic layer deposition (ALD) techniques. For example, in one implementation, the material to be deposited is Al₂O₃, which is deposited by an ALD process. In another example, the material to be deposited is SiO₂, which is deposited by a CVD process.

In some implementations, the material to be evaporated is fed to the crucible as a wire. In this case, the feeding rates and/or the wire diameters have to be chosen such that the desired ratio of the evaporation material and the reactive gas is achieved. In some implementations, the diameter of the feeding wire for feeding to the crucible is chosen between 0.5 mm and 2.0 mm (e.g., between 1.0 mm and 1.5 mm). These dimensions may refer to several feedings wires made of the evaporation material. In one implementation, feeding rates of the wire are in the range of between 50 cm/min and 150 cm/min (e.g., between 70 cm/min and 100 cm/min).

The crucible is heated in order to generate a vapor, which reacts with the reactive gas and/or plasma supplied at operation 540 to coat a surface 134 of the lithium metal film with a ceramic protective film such as the one or more ceramic protective film(s) 180. Typically, the crucible is heated by applying a voltage to the electrodes of the crucible, which are positioned at opposite sides of the crucible. Generally, according to implementations described herein, the material of the crucible is conductive. Typically, the material used as crucible material is temperature resistant to the temperatures used for melting and evaporating. Typically, the crucible of the present disclosure is made of one or more materials selected from the group comprising, consisting of, or consisting essentially of metallic boride, metallic nitride, metallic carbide, non-metallic boride, non-metallic nitride, non-metallic carbide, nitrides, titanium nitride, borides, graphite, TiB₂, BN, B₄C, and SiC.

The material to be deposited is melted and evaporated by heating the evaporation crucible. Heating can be conducted by providing a power source (not shown) connected to the first electrical connection and the second electrical connection of the crucible. For instance, these electrical connections may be electrodes made of copper or an alloy thereof. Thereby, heating is conducted by the current flowing through the body of the crucible. According to other implementations, heating may also be conducted by an irradiation heater of an evaporation apparatus or an inductive heating unit of an evaporation apparatus.

In certain implementations, the evaporation unit is typically heatable to a temperature of between 1,300 degrees Celsius and 1,600 degrees Celsius, such as 1,560 degrees Celsius. This is done by adjusting the current through the crucible accordingly, or by adjusting the irradiation accordingly. Typically, the crucible material is chosen such that its stability is not negatively affected by temperatures of that range. The speed of the substrate may be in the range of between 20 cm/min and 200 cm/min, more typically between 80 cm/min and 120 cm/min such as 100 cm/min. In these cases, the means for transporting should be capable of transporting the substrate at those speeds.

Optionally, at operation 540, the evaporated material is reacted with a reactive gas and/or plasma to form a ceramic protective film, such as the one or more ceramic protective film(s) 180, on a surface, such as a surface of the lithium anode film. According to some implementations, which can be combined with other implementations described herein, the reactive gases can be selected from the group comprising, consisting of, or consisting essentially of: oxygen-containing gases, nitrogen-containing gases, or combinations thereof. Examples of oxygen-containing gases that may be used with the implementations described herein include oxygen (O₂), ozone (O₃), oxygen radicals (O*), or combinations thereof. Examples of nitrogen containing gases that may be used with the implementations described herein include N₂, N₂O, NO₂, NH₃, or combinations thereof. According to some implementations, additional gases, typically inert gases such as argon can be added to a gas mixture comprising the reactive gas. Thereby, the amount of reactive gas can be more easily controlled. According to some implementations, which can be combined with other implementations described herein, the process can be carried out in a vacuum environment with a typical atmosphere of 1*10⁻² mbar to 1*10⁻⁶ mbar (e.g., 1*10⁻³ mbar or below; 1*10⁻⁴ mbar or below).

In some implementations where the evaporated material is reacted with plasma, the plasma is an oxygen-containing plasma. In one implementation, the oxygen-containing plasma is formed from an oxygen-containing gas and optionally an inert gas. The oxygen-containing gas may be selected from the group of N₂O, O₂, O₃, H₂O, and combinations thereof. The optional inert gas may be selected from the group of helium, argon, or combinations thereof. In one implementation, the oxygen-containing plasma is formed by a remote plasma source and delivered to the processing region to react with the evaporated material and form the second ceramic-containing layer. In another implementation, the oxygen-containing plasma is formed in-situ in the processing region and reacted with the evaporated material in the processing region to form the second-ceramic-containing layer.

In some implementations, the evaporated material is deposited directly on the surface of the lithium anode film to form the one or more ceramic protective films, such as the one or more ceramic protective film(s) 180. For example, in certain implementations, where the material to be evaporated is a metal oxide, the material to be deposited is deposited on the surface of the lithium anode film without the optional reactive gas/plasma treatment of operation 540.

At operation 550, an optional post-deposition treatment of the deposited dielectric layer is performed. The optional post-deposition treatment may include a post-deposition plasma treatment to densify the deposited dielectric layer, additional “functionalization” processes may be performed post-deposition; for example, complete oxidation of AlOₓ to form Al₂O₃, or deposition of polymer material to enhance puncture resistance of the membrane.

In summary, some of the benefits of the present disclosure, include the efficient formation of a thin anode stack. The thin anode stack includes an ultra-thin ceramic coating formed on a surface of a thin lithium metal film, which suppresses dendrite formation while maintaining the desired ionic conductivity. The lithium metal film may be deposited using techniques such as, for example, sputtering, thermal evaporation, e-beam evaporation, and atomic layer deposition. The ultra-thin ceramic coating may be deposited using PVD techniques at elevated temperatures. Deposition of the lithium metal film and the ultra-thin ceramic coating may be performed together in an integrated roll-to-roll too for high volume manufacturing.

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

The term “crucible” as used herein shall be understood as a unit capable of evaporating material that is fed to the crucible when the crucible is heated. In other words, a crucible is defined as a unit adapted for transforming solid material into vapor. Within the present disclosure, the term “crucible” and “evaporation unit” are used synonymously.

The term “processing drum” as used herein shall be understood as a roller, which is used during processing of a flexible substrate as described herein. In particular, a “processing drum” is to be understood as a roller, which is configured to support a flexible substrate during processing. More specifically, the processing drum as described herein may be arranged and configured such that the flexible substrate, e.g. a foil or a web, is wound around at least a part of the processing drum. For instance, during processing, typically the flexible substrate is in contact with at least a lower portion of the processing drum. In other words, during processing, the flexible substrate is wound around the processing drum such that the flexible substrate is in contact with a lower portion of the processing drum and the flexible substrate is provided below the processing drum.

The term “gas supply pipe” is to be understood as a pipe arranged and configured for providing a gas supply into a space between an evaporation crucible, particularly a set of evaporation crucibles, and a processing drum. For instance, the gas supply pipe may be positioned and/or shaped to direct a gas supply into a cloud of evaporated material between a first set of evaporation crucibles and the processing drum. Typically, the gas supply pipe includes openings or outlets, which are arranged and configured such that the gas supply from the gas supply pipe can be directed into the cloud of evaporated material. For instance, the openings or outlets may have at least one shape selected from the group consisting of a circular shape, a rectangular shape, an oval shape, a ring-like shape, a triangular-like shape, a polygon-like shape, or any shape suitable for delivering gas into the cloud of evaporated material.

While the foregoing is directed to implementations of the present disclosure, other and further implementations of the disclosure may be devised without departing from the basic scope thereof, and the scope thereof is determined by the claims that follow.

1. A deposition apparatus operable to coat a flexible substrate, comprising:
a first spool chamber capable of housing a storage spool operable to provide the flexible substrate;
a first deposition chamber arranged downstream from the first spool chamber and comprising a first coating drum capable of guiding the flexible substrate past a first plurality of deposition units capable of depositing a lithium metal film on the flexible substrate;
a second deposition chamber arranged downstream from the first deposition chamber and comprising a second coating drum capable of guiding the flexible substrate past a second deposition unit comprising an evaporation crucible capable of depositing a ceramic protective film on the lithium metal film;
a second spool chamber arranged downstream from the second deposition chamber and capable of housing a wind-up spool operable to wind the flexible substrate thereon after deposition; and
a roller assembly capable of transporting the flexible substrate along a partially convex and partially concave substrate transportation path from the first spool chamber to the second spool chamber.

2. The deposition apparatus of claim 1, further comprising a connection chamber arranged downstream from the first deposition chamber and upstream from the second deposition chamber.

3. The deposition apparatus of claim 1, wherein the first plurality of deposition units comprise an evaporation unit capable of depositing the lithium metal film on the flexible substrate.

4. The deposition apparatus of claim 3, wherein the evaporation unit is selected from a thermal evaporation unit, an electron beam evaporation unit, or a combination thereof.

5. The deposition apparatus of claim 1, wherein the first plurality of deposition units comprise sputter deposition units capable of depositing the lithium metal film on the flexible substrate.

6. The deposition apparatus of claim 4, wherein the second deposition unit comprises a plurality of evaporation crucibles aligned in a first line perpendicular to a travel direction of the flexible substrate and capable of generating a cloud of evaporated material to be deposited on the flexible substrate.

7. The deposition apparatus of claim 6, wherein the second deposition unit further comprises a gas supply pipe capable of supplying a gas supply directed into the cloud of evaporated material and positioned between the plurality of evaporation crucibles and the second coating drum.

8. The deposition apparatus of claim 7, wherein the flexible substrate comprises aluminum (Al), copper (Cu), zinc (Zn), nickel (Ni), cobalt (Co), manganese (Mn), chromium (Cr), stainless steel, or a combination thereof.

9. A method, comprising:
transferring a flexible substrate from a storage spool in a first spool chamber to a first deposition chamber arranged downstream from the first spool chamber, the first deposition chamber comprising a first coating drum capable of guiding the flexible substrate past a first plurality of deposition units;
guiding the flexible substrate past the first plurality of deposition units while depositing a lithium metal film on the flexible substrate via the first plurality of deposition units;
transferring the flexible substrate from the first deposition chamber to a second deposition chamber, the second deposition chamber comprising a second coating drum capable of guiding the flexible substrate past a second deposition unit comprising an evaporation crucible capable of depositing a ceramic protective film on the lithium metal film; and
guiding the flexible substrate past the evaporation crucible while depositing a ceramic protective film on the lithium metal film via the evaporation crucible.

10. The method of claim 9, further comprising:
transferring the flexible substrate from the second deposition chamber to a second spool chamber; and
winding the flexible substrate on a second spool positioned in the second deposition chamber.

11. The method of claim 10, further comprising transferring the flexible substrate through a connection chamber arranged downstream from the first deposition chamber and upstream from the second deposition chamber.

12. The method of claim 9, wherein the first plurality of deposition units comprise evaporation units capable of depositing the lithium metal film on the flexible substrate.

13. The method of claim 12, wherein the evaporation units are selected from a thermal evaporation unit, an electron-beam evaporation unit, or a combination thereof.

14. The method of claim 9, wherein the first plurality of deposition units comprise sputter deposition units capable of depositing the lithium metal film on the flexible substrate.

15. The method of claim 13, wherein the second deposition unit comprises a plurality of evaporation crucibles aligned in a first line perpendicular to a travel direction of the flexible substrate and capable of generating a cloud of evaporated material to be deposited on the flexible substrate.

16. The method of claim 15, wherein the second deposition unit further comprises a gas supply pipe capable of supplying a gas supply directed into the cloud of evaporated material and positioned between the plurality of evaporation crucibles and the second coating drum.

17. A method, comprising:
transferring a flexible substrate from a storage spool in a first spool chamber to a first deposition chamber arranged downstream from the first spool chamber, the first deposition chamber comprising a first coating drum capable of guiding the flexible substrate past a first plurality of deposition units, wherein the flexible substrate comprises an anode film;
guiding the flexible substrate past the first plurality of deposition units while depositing a lithium metal film on the anode film via the first plurality of deposition units;
transferring the flexible substrate from the first deposition chamber to a second deposition chamber through a connection chamber, the second deposition chamber comprising a second coating drum capable of guiding the flexible substrate past a second deposition unit comprising an evaporation crucible; and
guiding the flexible substrate past the evaporation crucible while depositing a ceramic protective film on the lithium metal film via the evaporation crucible.

18. The method of claim 17, wherein the evaporation units are selected from a thermal evaporation unit, an electron-beam evaporation unit, or a combination thereof.

19. The method of any of claim 18, wherein the flexible substrate comprises aluminum (Al), copper (Cu), zinc (Zn), nickel (Ni), cobalt (Co), manganese (Mn), chromium (Cr), stainless steel, or a combination thereof.

20. The method of any of claim 19, wherein the ceramic protective film is selected from porous aluminum oxide, porous-ZrO₂, porous-HfO₂, porous-SiO₂, porous-MgO, porous-TiO₂, porous-Ta₂O₅, porous-Nb₂O₅, porous-LiAlO₂, porous-BaTiO₃, ion-conducting garnet, anti-ion-conducting perovskites, porous glass dielectric, or a combination thereof.
